(19) United States
(12) Patent Application Publication
(10) Pub. No.: US 2024/0224812 A1
(43) Pub. Date: Jul. 4, 2024

(54) RELAXED PITCH BACKSIDE MAGNETO-RESISTIVE RANDOM ACCESS MEMORY INTEGRATION WITH SELF-ALIGNED MICRO STUD AND BACKSIDE POWER DISTRIBUTION NETWORK

(71) Applicant: INTERNATIONAL BUSINESS MACHINES CORPORATION, ARMONK, NY (US)

(72) Inventors: Tao Li, Slingerlands, NY (US); Ruilong Xie, Niskayuna, NY (US); Michael Rizzolo, Delmar, NY (US); Julien Frougier, Albany, NY (US)

(21) Appl. No.: 18/148,392

(22) Filed: Dec. 29, 2022

(51) Int. Cl. H10N 50/01; G11C 11/16; H10B 61/00; H10N 50/10; H10N 50/80

(52) U.S. Cl. CPC H10N 50/01; G11C 11/161; G11C 11/1655; G11C 11/1657; H10B 61/22; H10N 50/10; H10N 50/80

(57) ABSTRACT

A semiconductor device includes a magneto-resistive random access memory (MRAM) formed at a backside of a wafer. A self-aligning micro stud and silicide layer can directly electrically connect the MRAM to a source/drain (S/D) of a transistor in the MRAM region of the semiconductor device.

### BACKGROUND

The present disclosure generally relates to fabrication methods and resulting structures for semiconductor devices, and more particularly, to an improved process and resulting structures for a relaxed pitch backside magneto-resistive random access memory (MRAM) integration with self-aligned micro stud and backside power distribution network (BSPDN).

MRAM is a non-volatile computer memory technology. MRAM data is stored by magnetic storage elements. The elements are formed from two ferromagnetic layers, each of which can hold a magnetic field, separated by a thin insulating layer. One of the two layers is a reference magnet set to a particular polarity, while the remaining layer's field can be changed to match that of an external field to store memory and is termed the “free magnet” or “free-layer”. One of the two layers is a reference magnet set to a particular polarity, while the remaining layer's field can be changed to match that of an external field to store memory and is termed the “free magnet” or “free-layer”. This configuration is known as the magnetic tunnel junction (MTJ) and is the simplest structure for a MRAM bit.

One particular MRAM is a 1T-1R resistive memory build in back end of line (BEOL). Processes to form these MRAMs are to be compatible with front end of line (FEOL) and BEOL processes (e.g., compatible with a 400° C. anneal).

### SUMMARY

In one embodiment, a semiconductor device comprises a magneto-resistive random access memory (MRAM) formed at a backside of a wafer. A micro stud can electrically connect the MRAM to a source/drain (S/D) of a transistor. In some embodiments, a silicide layer can be disposed between the micro stud and the S/D.

In one embodiment, a semiconductor device comprises a magneto-resistive random access memory (MRAM) formed at a backside of a wafer. A micro stud can directly electrically connect the MRAM to a source/drain (S/D) of a transistor via an intermediate silicide layer. The micro stud and the silicide layer are self-aligned with the S/D of the transistor.

In one embodiment, a method of forming a semiconductor device comprises forming a first sacrificial placeholder at a first depth under a source/drain (S/D) of a magneto-resistive random access memory (MRAM) transistor in an MRAM region. A second sacrificial placeholder can be formed at a second depth under a S/D of a logic transistor, wherein the first depth is deeper than the second depth. The first sacrificial placeholder can be replaced with a micro stud and an MRAM stack can be deposited on the backside of the semiconductor device, where the MRAM stack is electrically connected to the micro stud. The MRAM stack can be patterned into an MRAM while the second sacrificial placeholder is buried within an interlayer dielectric.

By virtue of the concepts discussed herein, improved process and resulting structures provide a relaxed pitch backside magneto-resistive random access memory (MRAM) integration with self-aligned micro stud and backside power distribution network. Such a system improves conventional front side MRAM placement by providing a direction between the MRAM and the gate S/D, thus improving MRAM performance.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 depicts an electrical diagram illustrating an MRAM cell connections according to an illustrative embodiment.

FIG. 2A depicts a top-down reference view of an MRAM region of a semiconductor device after an initial set of processing operations according to an illustrative embodiment.

FIG. 2B depicts a top-down reference view of a logic region of a semiconductor device after an initial set of processing operations according to an illustrative embodiment.

FIGS. 3A and 3B depict, respectively, a logic region and an MRAM region of the semiconductor device of FIGS. 2A and 2B, illustrating pillar formation, including nanosheet (NS) stack patterning, shallow trench isolation (STI) formation, gate patterning, bottom dielectric isolation (BDI) and spacer formation, NS recess, and inner spacer formation.

FIGS. 4A and 4B depict, respectively, a logic region and an MRAM region of the semiconductor device of FIGS. 2A and 2B, illustrating organic planarization layer deposition and placeholder patterning, consistent with an illustrative embodiment.

FIGS. 5A and 5B depict, respectively, a logic region and an MRAM region of the semiconductor device of FIGS. 2A and 2B, illustrating using a block mask to open MRAM region to increase placeholder depth, consistent with an illustrative embodiment.

FIGS. 6A and 6B depict, respectively, a logic region and an MRAM region of the semiconductor device of FIGS. 2A and 2B, illustrating OPL removal and placeholder fill deposition, consistent with an illustrative embodiment.

FIGS. 7A and 7B depict, respectively, a logic region and an MRAM region of the semiconductor device of FIGS. 2A and 2B, illustrating source/drain (S/D) epi formation, interlayer dielectric (ILD) deposition and chemical-mechanical planarization (CMP), consistent with an illustrative embodiment.

FIGS. 8A and 8B depict, respectively, a logic region and an MRAM region of the semiconductor device of FIGS. 2A and 2B, illustrating dummy gate removal, SiGe removal, replacement high-k metal gate (HKMG) formation, middle of line (MOL) and back end of line (BEOL) interconnect formation, and carrier wafer bonding, consistent with an illustrative embodiment.

FIGS. 9A and 9B depict, respectively, a logic region and an MRAM region of the semiconductor device of FIGS. 2A and 2B, illustrating wafer flip, and substrate removal, stopping on the etch stop layer, consistent with an illustrative embodiment.

FIGS. 10A and 10B depict, respectively, a logic region and an MRAM region of the semiconductor device of FIGS. 2A and 2B, illustrating etch stop layer and Si removal, backside ILD deposition, and CMP, consistent with an illustrative embodiment.

FIGS. 11A and 11B depict, respectively, a logic region and an MRAM region of the semiconductor device of FIGS. 2A and 2B, illustrating exposed placeholder removal, forming the micro stud, including a silicide connector, and CMP, consistent with an illustrative embodiment.

FIGS. 12A and 12B depict, respectively, a logic region and an MRAM region of the semiconductor device of FIGS. 2A and 2B, illustrating MRAM stack deposition, consistent with an illustrative embodiment.

FIGS. 13A and 13B depict, respectively, a logic region and an MRAM region of the semiconductor device of FIGS. 2A and 2B, illustrating MRAM patterning by ion beam etching (IBE), consistent with an illustrative embodiment.

FIGS. 14A and 14B depict, respectively, a logic region and an MRAM region of the semiconductor device of FIGS. 2A and 2B, illustrating MRAM Protective spacer deposition and reactive ion etching (RIE), and back interlayer dielectric (BILD) pull back to reveal place holder at logic region, consistent with an illustrative embodiment.

FIGS. 15A and 15B depict, respectively, a logic region and an MRAM region of the semiconductor device of FIGS. 2A and 2B, illustrating placeholder removal, metal fill, and recess, consistent with an illustrative embodiment.

FIGS. 16A and 16B depict, respectively, a logic region and an MRAM region of the semiconductor device of FIGS. 2A and 2B, illustrating backside power rail formation and connection to the backside power distribution network (BSPDN) in the logic region and bit line connection and BSPDN interconnect formation, consistent with an illustrative embodiment.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surface, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

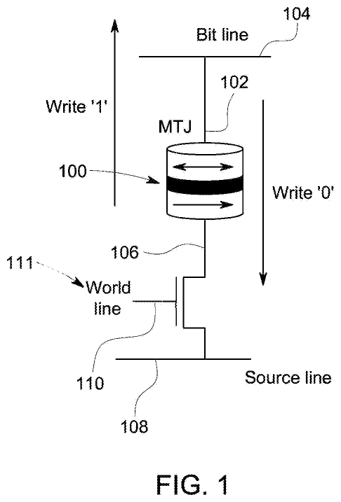

FIG. 1 depicts an electrical diagram illustrating an MRAM cell 100 (also simply referred to as MRAM 100) and its connections, according to an illustrative embodiment. One electrical connection 102 can connect the MRAM 100 to a bit line 104. Another electrical connection 106 can connect the MRAM 100 to a source line electrical connection 108 through a logic cell. A further word line electrical connection 110 can connect the MRAM 100 to a word line 111. A first source/drain of the logic cell can connect to the source line electrical connection 108. A second source/drain of the logic cell can connect to electrical connection 106. The word line 111 can control the logic cell gate.

Conventional MRAM cells are located on the frontside of the wafer, which involves not only the word line and the source line to be on the front side of the wafer, but also the bit line to be additionally located on the front side of the wafer. Aspects of the present disclosure move the MRAM 100 to the backside of the wafer, thus relieving the routing congestion that is present in conventional, front-located MRAM cells. With the MRAM on the backside of the wafer, the bit line can also be on the backside of the wafer. Therefore, the word line and the source line has a more relaxed space. With the MRAM on the backside of the wafer, this enable the MRAM to be very stable and very close to the transistor, permitting the MRAM to directly contact the logic structure S/D and thus promoting the performance of the MRAM. Further, the backside MRAM pillar size can be about 2 contacted poly pitch (CPP), which is around 100 nm, and therefore compatible with MRAMs with larger cell size. Also, in one aspect, the backside MRAM proposed in the present disclosure is fully compatible with a direct backside contact at the logic.

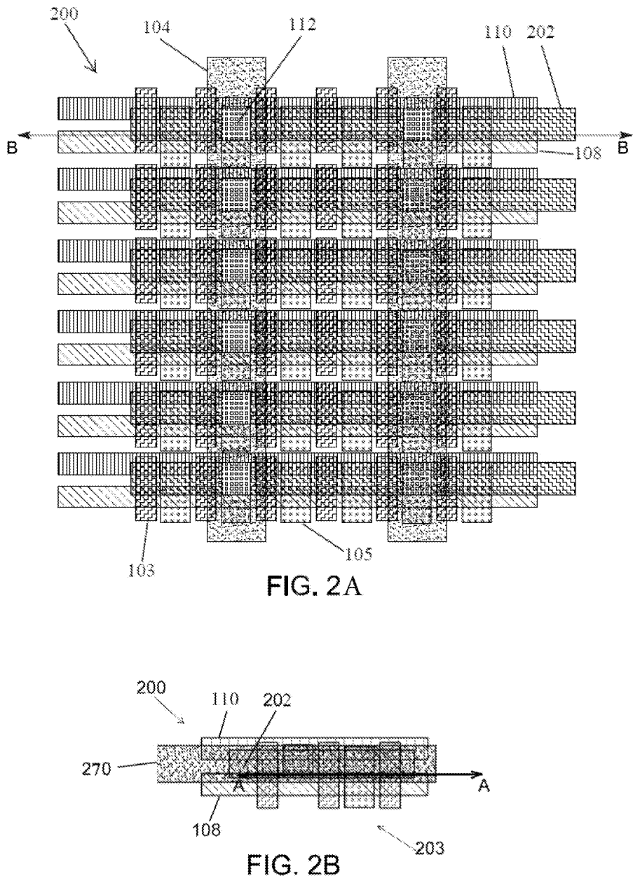

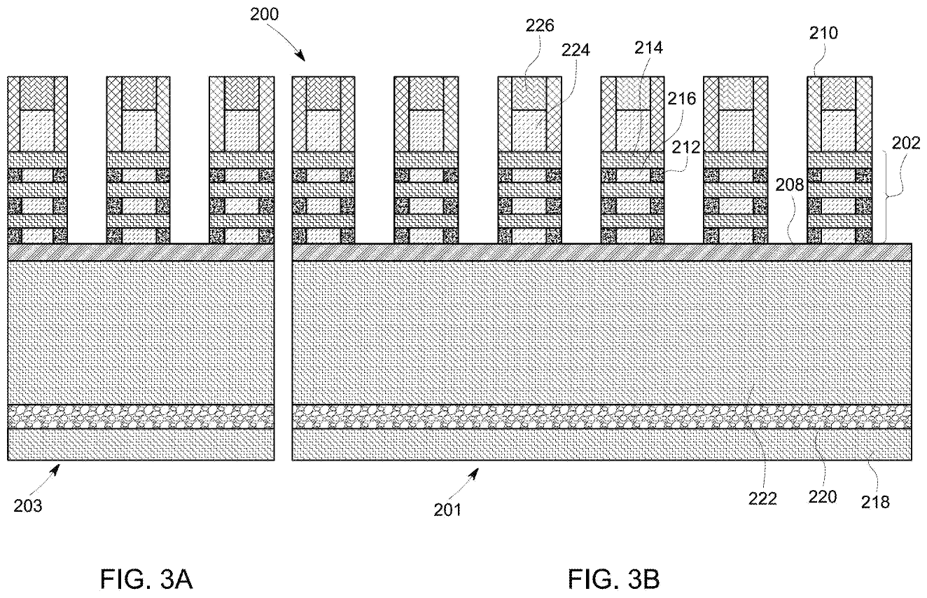

FIG. 2A illustrates a top down view of a wafer 200 (also referred to as semiconductor structure) in its completed form. The horizontal arrow B-B illustrates a line along which the cross-section of the MRAM regions 201 (see FIG. 3B, for example) of the subsequent figures are taken. The wafer 200 can include the word line electrical connection 110 and the source line electrical connection 108 on the front of the wafer 200. The bit line 104 can be located on the back side of the wafer 200. The MRAM 100 may be located below a direct backside contact 112 visible in the top down view of FIG. 2A. Middle-of-line (MOL) processing can form S/D MOL contacts 107, as well as the wiring for the local interconnect structure overlying the semiconductor device structure and the wiring for functional gate structures 105.

FIG. 2B illustrates a top down view of a logic region 203 of the wafer 200. The horizontal arrow A-A illustrates a line along which the cross-section of the logic region 203 (see FIG. 3A, for example) of the subsequent figures are taken. Instead of having wafer backside bit line 104 running in a direction perpendicular of the word line 110 and the source line 108 at the wafer front side, as in FIG. 2A, the normal logic cell (i.e., without an MRAM thereunder, as illustrated in FIGS. 3A, 4A, 5A . . . 16A) can have a backside power rail 270 running in parallel direction of the word line 110 and the source line 108.

Turning now to a more detailed description of fabrication operations and resulting structures according to aspects of the present disclosure, FIGS. 3A-16B depict the wafer 200 after various fabrication operations in accordance with aspects of the present disclosure. Although the cross-sectional diagrams depicted in FIGS. 3A-16B are two-dimensional, it is understood that the diagrams depicted in FIGS. 3A-16B represent three-dimensional structures. The top-down reference view shown in FIGS. 2A and 2B provides a reference point for the various cross-sectional views shown in FIGS. 3A-16B.

FIGS. 3A and 3B depict, respectively, a logic region 203 and an MRAM region 201 of the semiconductor device of FIGS. 2A and 2B, illustrating nanosheet (NS) stack 202 patterning, shallow trench isolation (STI) formation (not shown from the current cross-section), dummy gate patterning, bottom dielectric isolation 208 (BDI 208) and spacer 210 formation, NS recess with inner spacer 212 formation. As mentioned above, conventional processes may be used for arriving at the initial fabrication pattern of FIGS. 3A and 3B. A substrate 218, such as a silicon substrate, can support an etch stop layer 220 having a semiconductor layer 222, such as a silicon layer, disposed thereupon.

A hard mask 226 can be placed above the dummy gates 224 after gate patterning. For example, the dummy gate serves as a placeholder and permits the placement of the source and drain regions of the device. Following formation of the source and drain regions, the dummy gate can be removed and replaced with a replacement gate stack. Thus, potential damage to the replacement gate stack (e.g., from processing conditions such as dopant implant and/or activation anneals) can be avoided since the gate stack is not formed until the end of the process.

As shown in FIG. 3B, at least one dummy gate 224 is formed over a portion of each of the nanowire stacks that will serve as a channel region of the device. The dummy gate 224 can be formed by blanket depositing a dummy gate material onto, and in between, the nanowire stacks and then patterning the dummy gate material into one or more individual dummy gates 224. Suitable dummy gate materials include, but are not limited to, poly-silicon (or poly-Si). As highlighted above, with the dummy gate 224 in place, the source and drain regions of the device can then be formed.

The etch stop layer 220 can be used for the BSPND process. During grinding of the substrate 218, CMP and wet etch, the process may generate large cross wafer thickness variation, and the etch stop layer 220 can have a selectivity to the semiconductor layer 222 such that a wet chemistry can selectively remove etch stop layer 220 and overcome this incoming thickness variation generated during removal of the substrate 218. Then, the remaining etch stop layer cross wafer thickness variation is considered small and is proper for the backside process.

The substrate 218 and the semiconductor layer 222 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments, the nanosheet stacks 202 can initially include one or more semiconductor layers 214 alternating with one or more sacrificial layers 216, also referred to as sacrificial layers 216. In some embodiments, the semiconductor layers 214 and the sacrificial layers 216 are epitaxially grown layers. It is understood that the nanosheet stacks 202 can include any number of nanosheets alternating with a corresponding number of sacrificial layers. For example, the nanosheet stacks 202 can include two nanosheets, five nanosheets, eight nanosheets, 30 nanosheets (e.g., 3D NAND), or any number of nanosheets, along with a corresponding number of sacrificial layers (i.e., as appropriate to form a nanosheet stack having a bottommost sacrificial layer under a bottommost nanosheet and a sacrificial layer between each pair of adjacent nanosheets).

The semiconductor layers 214 can be made of any suitable material such as, for example, monocrystalline silicon or silicon germanium. In some embodiments, the semiconductor layers 214 are silicon nanosheets. In some embodiments, the semiconductor layers 214 have a thickness of about 4 nm to about 15 nm, for example 10 nm, although other thicknesses are within the contemplated scope of the present disclosure. In some embodiments, the substrate 218 and the semiconductor layers 214, 222 can be made of a same semiconductor material. In other embodiments, the substrate 218 can be made of a first semiconductor material, and the semiconductor layers 214, 222 can be made of a second and/or third semiconductor material.

The sacrificial layers 216 can be silicon or silicon germanium layers, depending on the material of the semiconductor layers 214 to meet etch selectivity requirements. For example, in embodiments where the semiconductor layers 214 are silicon nanosheets, the sacrificial layers 216 can be silicon germanium layers. In embodiments where the semiconductor layers 214 are silicon germanium nanosheets, the sacrificial layers 216 can be silicon germanium layers having a germanium concentration that is greater than the germanium concentration in the semiconductor layers 214. For example, if the semiconductor layers 214 are silicon germanium having a germanium concentration of 5 percent (sometimes referred to as SiGe5), the sacrificial layers 216 can be silicon germanium layers having a germanium concentration of about 25 (SiGe25), although other germanium concentrations are within the contemplated scope of the present disclosure. In some embodiments, the sacrificial layers 216 have a thickness of about 8 nm to about 15 nm, for example 10 nm, although other thicknesses are within the contemplated scope of the present disclosure.

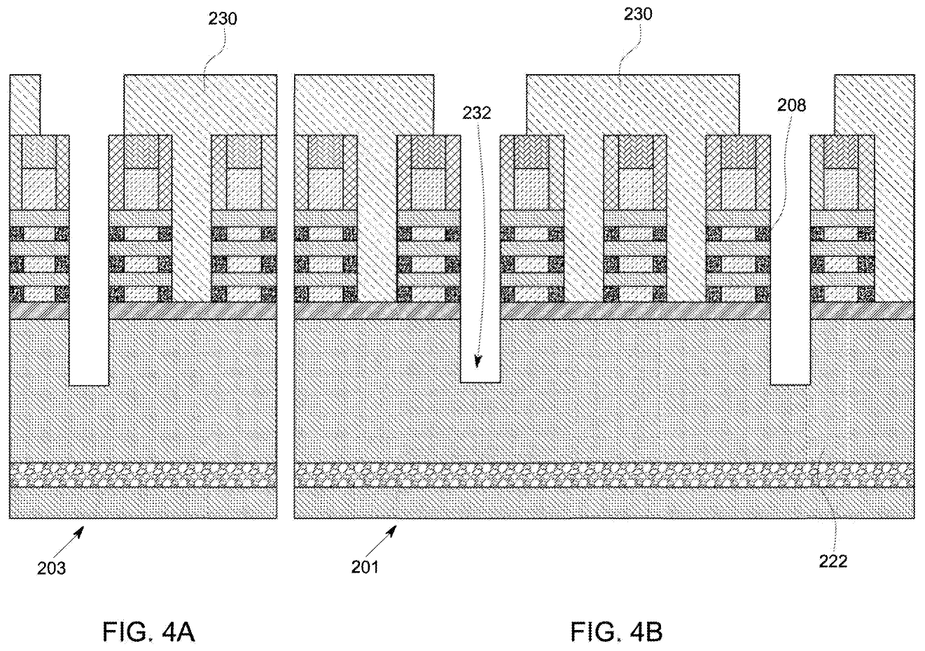

As shown in FIGS. 4A and 4B, an organic planarization layer 230 (OPL 230) can be deposited and placeholder positions 232 can be patterned by etching between dummy gates 224, through the BDI 208 and partially into the semiconductor layer 222. The OPL 230 can include a photo-sensitive organic polymer having a light-sensitive material that, when exposed to electromagnetic (EM) radiation, is chemically altered and thus configured to be removed using a developing solvent. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). More generally, for example, the OPL 230 can include any organic polymer and a photo-active compound having a molecular structure that can attach to the molecular structure of the organic polymer. In some embodiments, the OPL 230 material is selected to be compatible with an overlying antireflective coating (not shown) and/or an overlying photoresist (not shown). In some embodiments, the OPL 230 can be applied using spin coating technology, although other techniques are within the contemplated scope of the present disclosure.

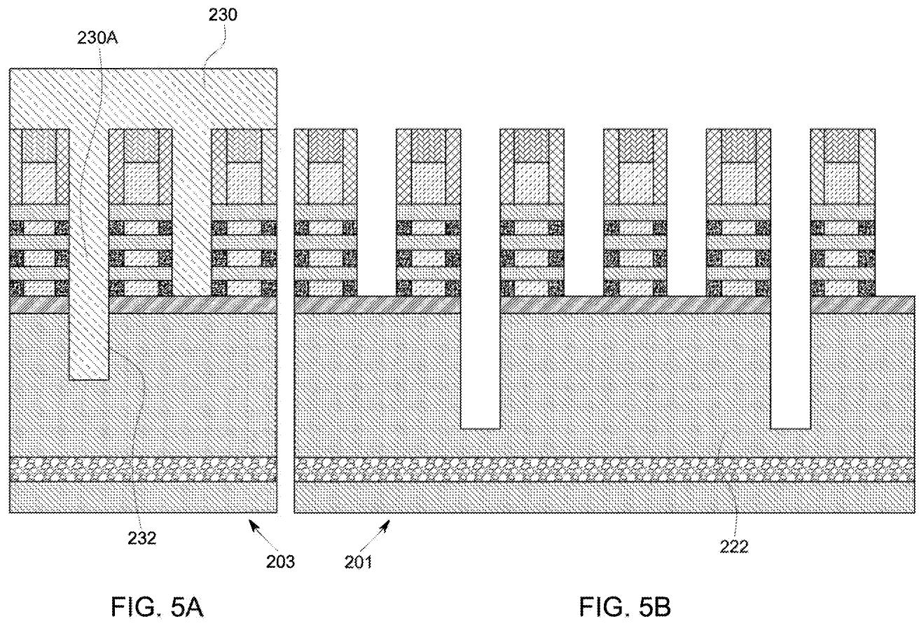

As shown in FIGS. 5A and 5B, OPL 230 may be removed and additional OPL 230A may be applied as a block mask and the placeholder positions 232 in the MRAM region 201 can be etched to an increased depth in the semiconductor layer 222 (as compared to the depth of the placeholder position 232 in the logic region 203). The etching of the placeholder positions 232 may be performed by various etching techniques, such as reactive ion etching (RIE), dry etching, wet etching, ion beam etching, plasma etching, laser ablation, or the like.

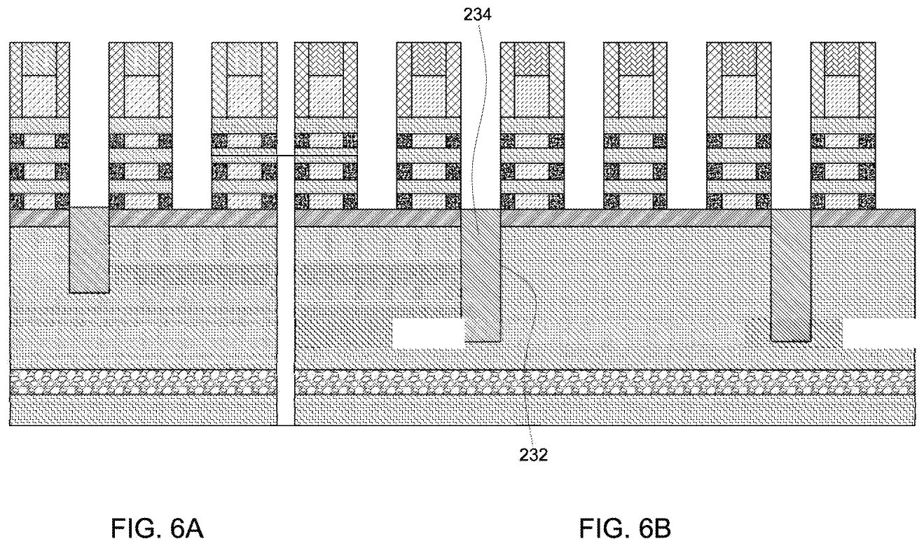

As shown in FIGS. 6A and 6B, the additional OPL 230A can be removed and placeholder fill 234 can be deposited in the placeholder positions 232. The placeholder fill 234 may be titanium oxide, aluminum oxide or the like. In some embodiments, the OPL 230A can be removed using, for example, ashing or any other suitable removal technique.

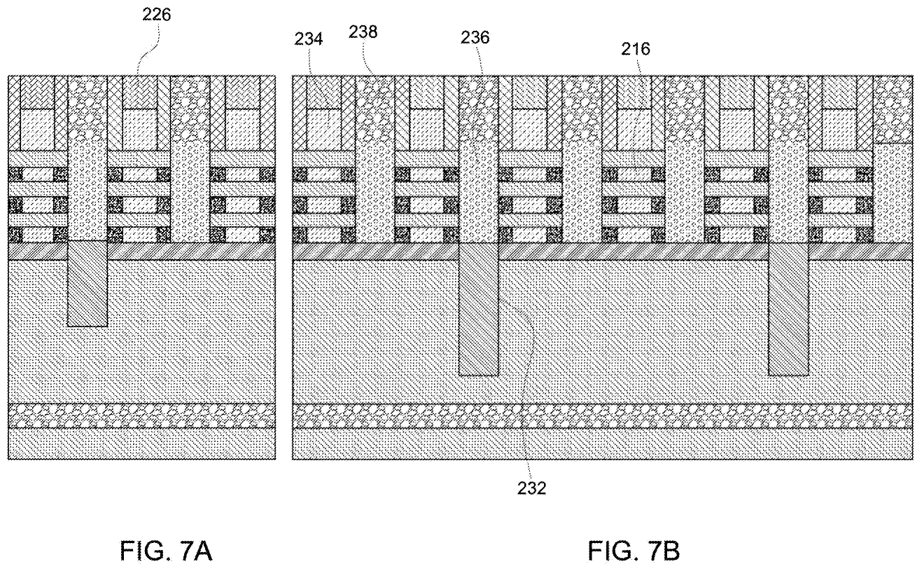

As shown in FIGS. 7A and 7B, the S/D epi 236 can be epitaxial formed and/or grown and an ILD 238 can be deposited on top of the S/D epi 236. CMP may also be performed at this stage. The term “epitaxially formed and/or grown” means the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments of the disclosure, epitaxial growth and/or deposition processes can be selective to forming on semiconductor surface, and may or may not deposit material on other exposed surfaces, such as silicon dioxide or silicon nitride surfaces. The ILD 238 can be made of any suitable dielectric material, such as, for example, oxides, a low-k dielectric, nitrides, silicon nitride, silicon oxide, SiON, SiC, SiOCN, and/or SiBCN.

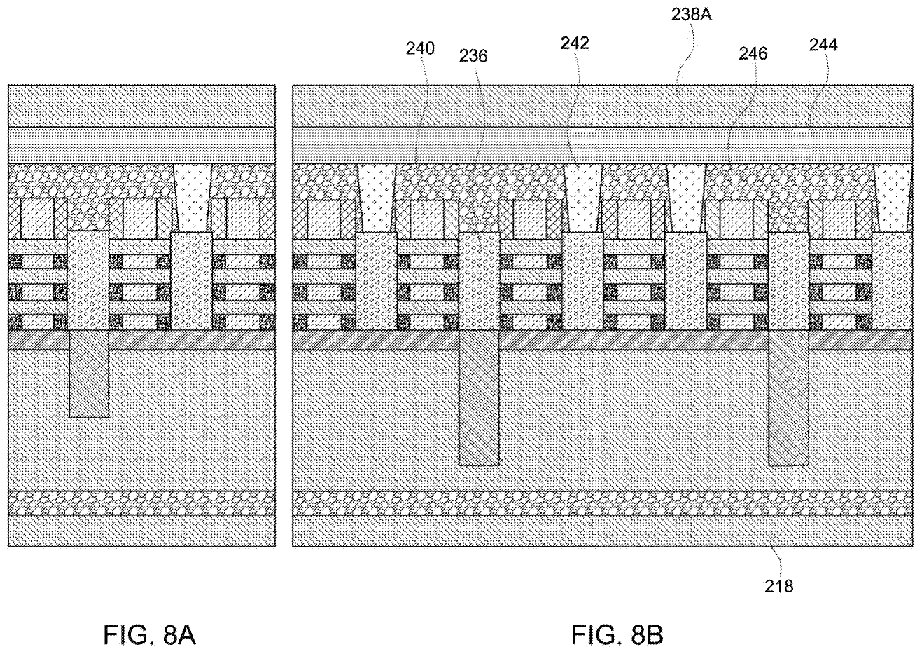

As shown in FIGS. 8A and 8B, the dummy gates 224 removal, the sacrificial layers 216 (SiGe layers) can be removed, and the dummy gates 224 and the sacrificial layers 216 (SiGe layers) can be replaced with HKMG 240. The hard mask 226 can be removed and replaced with additional ILD 238A. Source drain contacts 242 can be formed between the S/D epi 236 and the BEOL interconnect 244 formation. Carrier wafer 246 can be bonded to the BEOL interconnect 244. The dummy gates 224 and the sacrificial layers 216 may be removed by, for example, chemical wet etching.

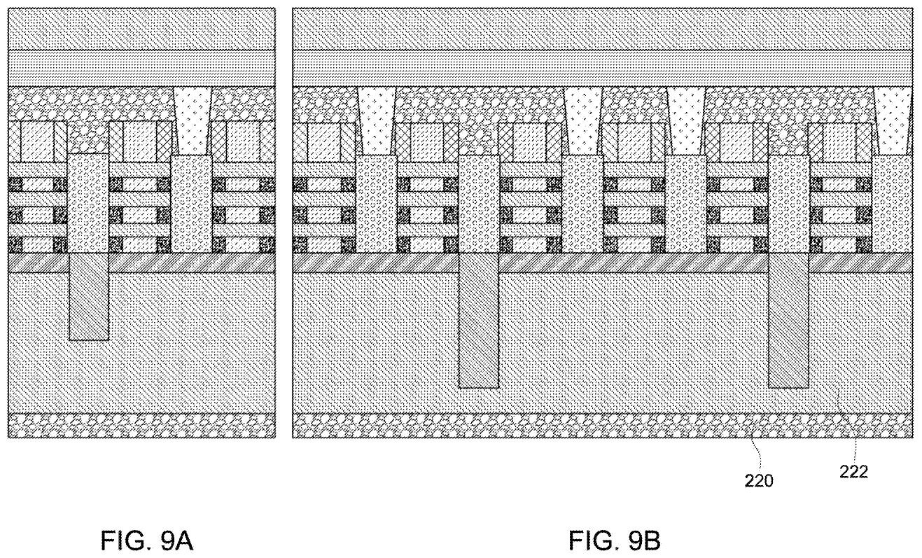

As shown in FIGS. 9A and 9B, the wafer can be flipped and the substrate 218 can be removed using any suitable removal technique, e.g., grinding, CMP and/or wet etch, as described herein or otherwise suitable methods, stopping at the etch stop layer 220.

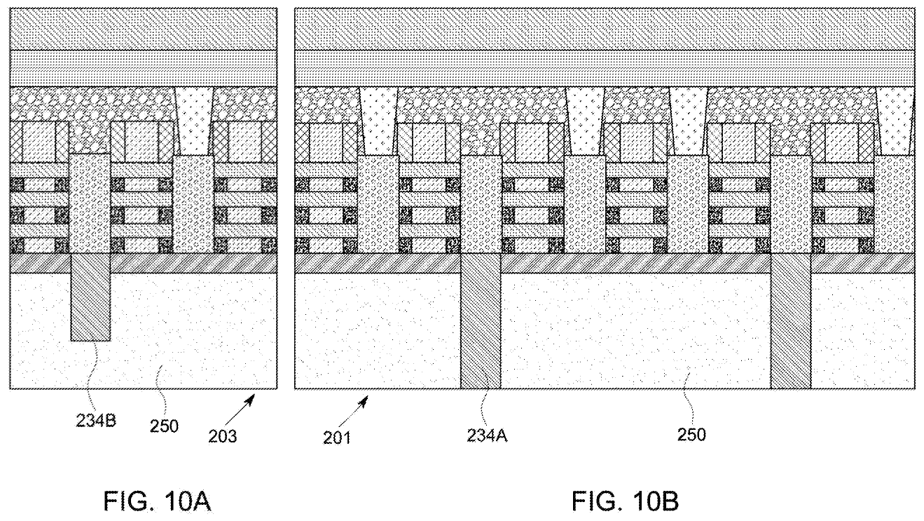

As shown in FIGS. 10A and 10B, the etch stop layer 220 and the semiconductor layer 222 are removed and ILD 250 is deposited. CMP can be performed at this stage to expose the placeholders 234A in the MRAM region 201, while the logic region placeholder 234B is encased within the ILD 250. The removal of the etch stop layer 220 and the semiconductor layer 222 may be performed by any suitable removal technique, such as grinding, wet etch, stripping, plasma ashing, reactive ion etching, or the like.

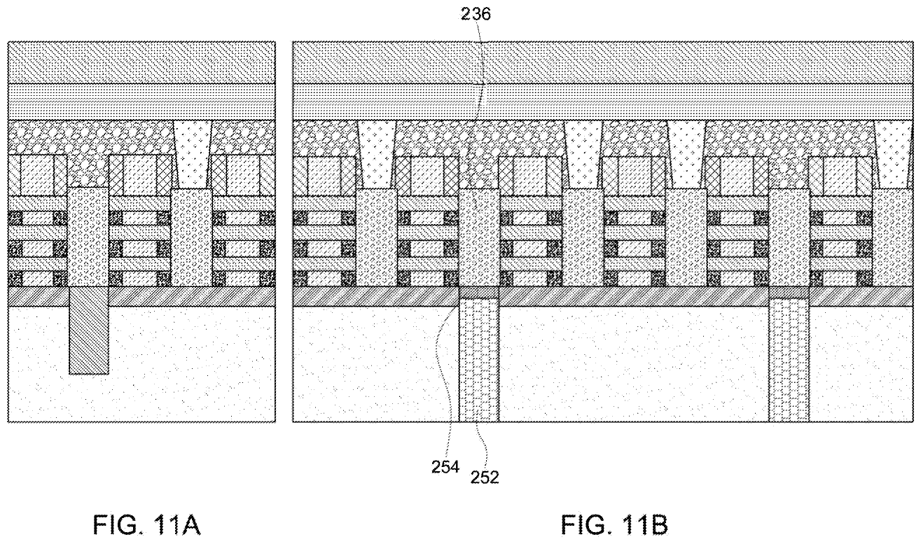

As shown in FIGS. 11A and 11B, the exposed placeholders 234A in the MRAM region 201 are removed and a micro stud 252 is formed in its place. The micro stud 252 may be made from various materials, such as TaN. A silicide connector 254 can be formed on the S/D epi 236 prior to forming the micro stud 252. The silicide connector 254 can be deposited by PVD. For example, a titanium silicide may be deposited at 300 C, thereby resulting in no thermal concern during its deposition. CMP can be performed at this stage. The micro stud 252 and the silicide connector 254 are self-aligning with the S/D of the transistor in that they are formed in the placeholder region that was originally formed from the front side of the wafer 200 in between gate stacks.

In some embodiments, the micro stud 252 can have a critical dimension (CD) (a width of the micro stud 252 as shown in FIGS. 11A and 11B) that is substantially smaller than the width of the MRAM. For example, the micro stud 252 may have a width that is from about 10 percent to about 60 percent of that of the MRAM. Such a width permits placement within the backside of the wafer and permits a high density of such backside placed MRAMs. In one embodiment, the MRAM may have a width of about 2CPP (100 nm), while the micro stud 252 may have a CD from about 10 nm to about 30 nm.

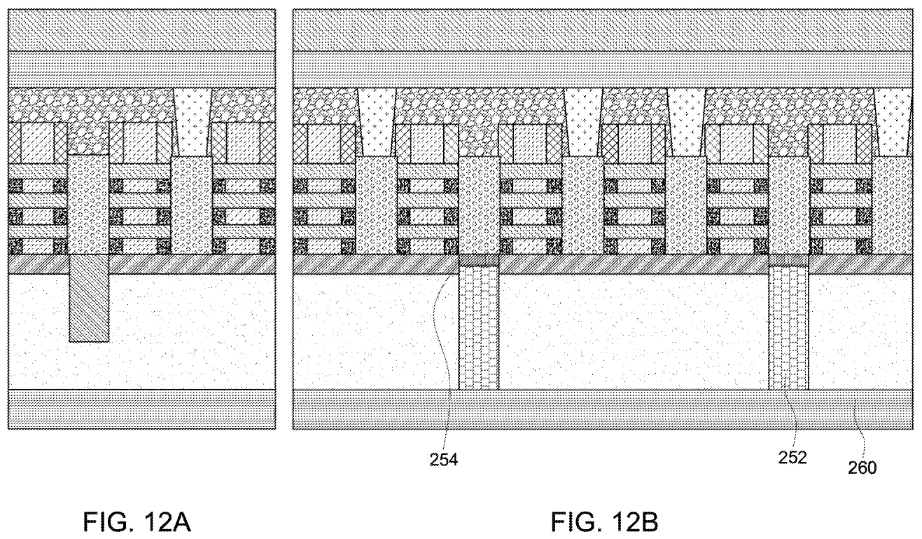

As shown in FIGS. 12A and 12B, an MRAM stack 260 can be formed on the back side, electrically connected to the micro stud 252 and thus, directly connected to the S/D of the transistor.

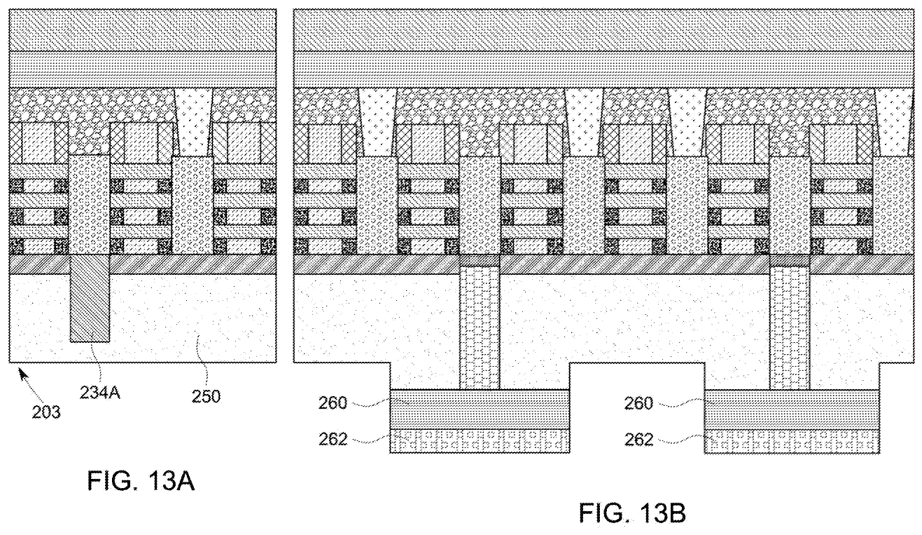

As shown in FIGS. 13A and 13B, A hard mask 262 may be deposited on the MRAM stack 260. The MRAM stack 260 can be patterned by, for example, ion beam etching (IBE). The hard mask 262 can be made of any suitable material, such as, for example, a silicon nitride.

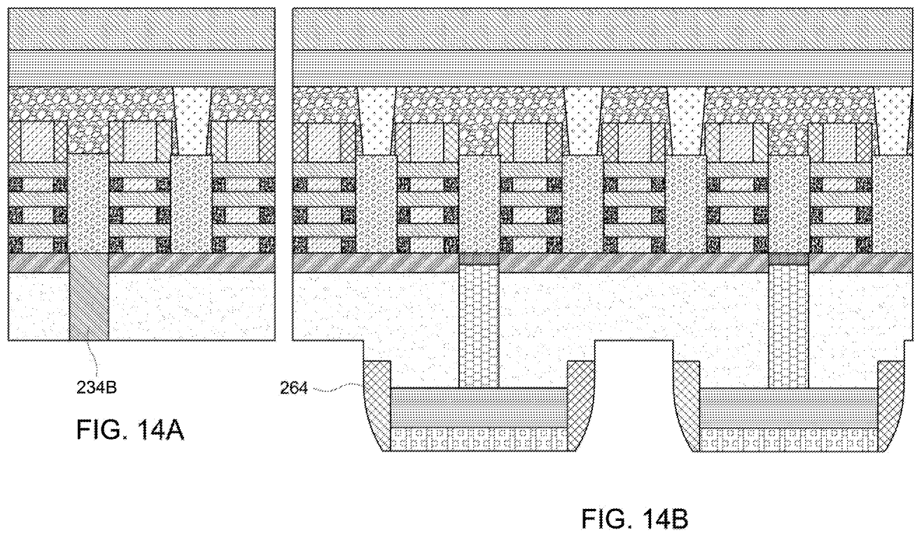

As shown in FIGS. 14A and 14B, an MRAM protective spacer 264 can be formed by reactive ion etching (RIE), for example, and back ILD 250 in the logic region 203 can be pulled back to reveal the logic region placeholder 234B. The ILD 250 may be removed by any suitable means, such as wet etching, drying etching, or the like.

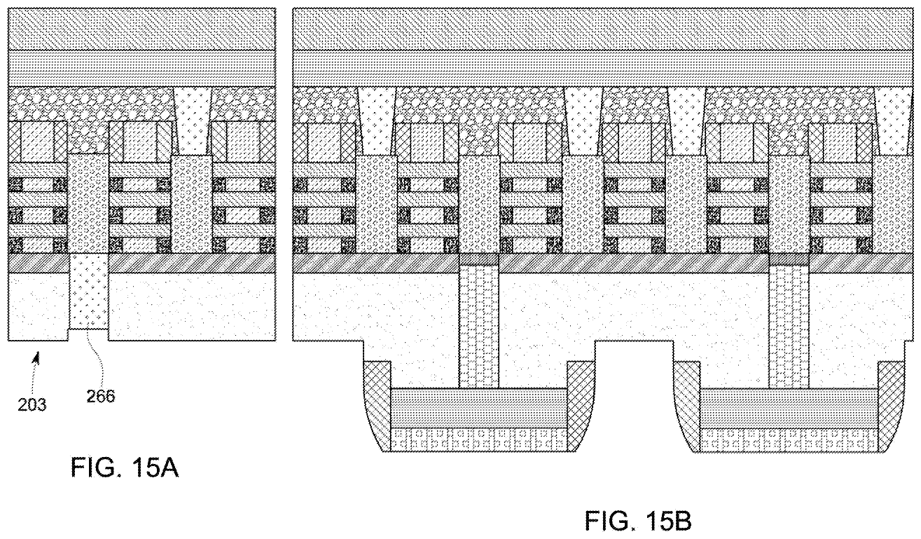

As shown in FIGS. 15A and 15B, the logic region placeholder 234B can be removed and a metal fill 266 can be added for a backside contact area in the logic region 203.

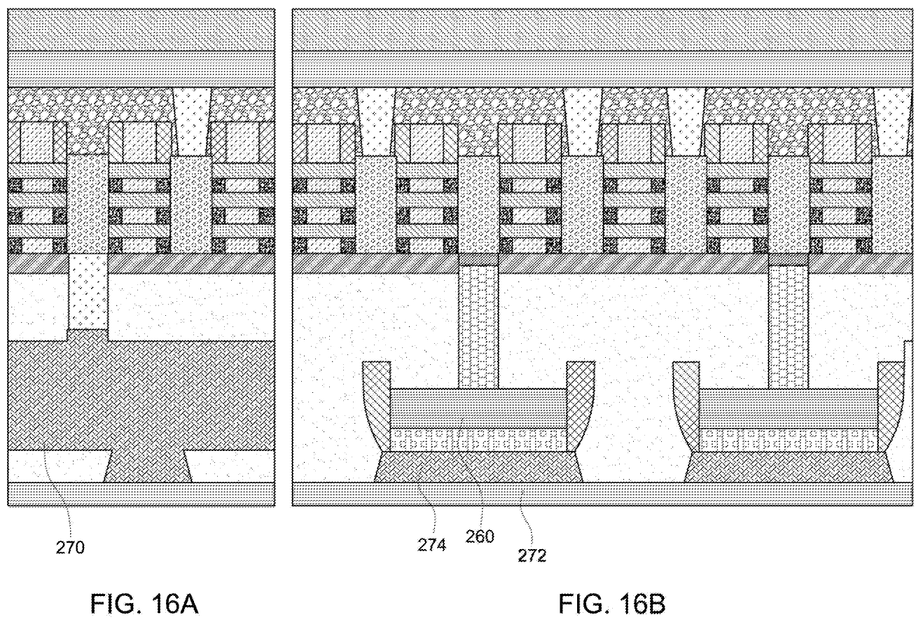

As shown in FIGS. 16A and 16B, a backside power rail 270 can be formed can connect to the backside power distribution network interconnect 272 (BSPDN interconnect 272) in the logic region 203 and a bit line connection via 274 can connect MRAM stack 260 to the BSPDN interconnect 272.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Importantly, although the operational/functional descriptions described herein may be understandable by the human mind, they are not abstract ideas of the operations/functions divorced from computational implementation of those operations/functions. Rather, the operations/functions represent a specification for an appropriately configured computing device. As discussed in detail above, the operational/functional language is to be read in its proper technological context, i.e., as concrete specifications for physical implementations.

Accordingly, one or more of the methodologies discussed herein may obviate a need for time consuming data processing by the user. This may have the technical effect of reducing computing resources used by one or more devices within the system. Examples of such computing resources include, without limitation, processor cycles, network traffic, memory usage, storage space, and power consumption.

It should be appreciated that aspects of the teachings herein are beyond the capability of a human mind. It should also be appreciated that the various embodiments of the subject disclosure described herein can include information that is impossible to obtain manually by an entity, such as a human user. For example, the type, amount, and/or variety of information included in performing the process discussed herein can be more complex than information that could be reasonably be processed manually by a human user.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features and objects that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising:
a magneto-resistive random access memory (MRAM) formed at a backside of a wafer; and
a micro stud electrically connecting the MRAM to a source/drain (S/D) of a transistor.

2. The semiconductor device of claim 1, further comprising a silicide layer electrically connecting the MRAM with the micro stud.

3. The semiconductor device of claim 2, wherein the S/D is directly electrically connected to the MRAM by the silicide layer and the micro stud.

4. The semiconductor device of claim 2, wherein the micro stud and the silicide layer are aligned with the S/D of the transistor.

5. The semiconductor device of claim 2, wherein the micro stud has a critical dimension (CD) that is smaller than a width of the MRAM.

6. The semiconductor device of claim 5, wherein the CD of the micro stud is from 10 percent to 60 percent of the width of the MRAM.

7. The semiconductor device of claim 1, wherein the MRAM has a pillar size of 2 contacted poly pitch (CPP).

8. The semiconductor device of claim 1, further comprising a backside power distribution network at the backside of the wafer.

9. The semiconductor device of claim 8, further comprising a bit line connection via interconnecting the MRAM to a bit line at the backside power distribution network.

10. The semiconductor device of claim 1, further comprising:
a word line electrical connection interconnecting the MRAM to a word line at a front side of the wafer; and
a source line electrical connection interconnecting the MRAM to a source line at a front side of the wafer.

11. The semiconductor device of claim 1, wherein a logic region placeholder is encased in interlayer dielectric during formation of the micro stud.

12. A semiconductor device comprising:
a magneto-resistive random access memory (MRAM) formed at a backside of a wafer; and
a micro stud directly electrically connecting the MRAM to a source/drain (S/D) of a transistor via an intermediate silicide layer,
wherein the micro stud and the intermediate silicide layer are aligned with the S/D of the transistor.

13. The semiconductor device of claim 12, wherein the micro stud has a critical dimension (CD) that is smaller than a width of the MRAM.

14. The semiconductor device of claim 12, further comprising:
a backside power distribution network at the backside of the wafer; and
a bit line connection via interconnecting the MRAM to a bit line at the backside power distribution network.

15. The semiconductor device of claim 12, wherein a logic region placeholder is encased in interlayer dielectric during formation of the micro stud and the intermediate silicide layer.

16. A semiconductor device comprising:
a magneto-resistive random access memory (MRAM) formed at a backside of a wafer;
a micro stud directly electrically connecting the MRAM to a source/drain (S/D) of a transistor via an intermediate silicide layer;
a backside power distribution network at the backside of the wafer; and
a bit line connection via interconnecting the MRAM to a bit line at the backside power distribution network.

17. The semiconductor device of claim 16, wherein the micro stud and the intermediate silicide layer are aligned with the S/D of the transistor.

18. The semiconductor device of claim 16, wherein the micro stud has a critical dimension (CD) that is smaller than a width of the MRAM.

19. The semiconductor device of claim 18, wherein the CD of the micro stud is from 10 percent to 60 percent of the width of the MRAM.

20. The semiconductor device of claim 16, wherein the MRAM has a pillar size of 2 contacted poly pitch (CPP).
